(19) United States
(12) Patent Application Publication
(10) Pub. No.: US 2015/0069440 A1
(43) Pub. Date: Mar. 12, 2015

(54) LIGHT EMITTING DIODE AND METHOD OF MANUFACTURING THE SAME

(71) Applicants: Ja-Soon Jang, Daegu (KR); Seon-Ho Jang, Gyeongsan-si (KR); Sei-Min Kim, Daegu (KR)

(72) Inventors: Ja-Soon Jang, Daegu (KR); Seon-Ho Jang, Gyeongsan-si (KR); Sei-Min Kim, Daegu (KR)

(73) Assignee: Industry -Academic Cooperation Foundation, Yeungnam University, Gyeongsan-si, Gyeongsanbuk-do (KR)

(21) Appl. No.: 14/390,395

(22) PCT Filed: Apr. 12, 2012
(86) PCT No.: PCT/KR2012/002770

§ 371 Date: Oct. 2, 2014

(30) Foreign Application Priority Data
Apr. 5, 2012 (KR) 10-2012-0035588

(51) Int. Cl. H01L 33/58; H01L 33/42

(52) U.S. Cl. CPC H01L 33/58; H01L 33/42; H01L 2933/0016; H01L 2933/0058
USPC 257/98; 438/29

(57) ABSTRACT

Provided is a light emitting diode having a nanostructure capping pattern and a method of manufacturing the same. A light-emitting structure including a first semiconductor layer, a second semiconductor layer, and an active layer between the first and second semiconductor layers is provided. A nanostructure is provided on the light-emitting structure and a nanostructure capping pattern covering the nanostructure is provided. A refractive index of the nanostructure capping pattern is higher than that of air and lower than that of the nanostructure.

### TECHNICAL FIELD

The present inventive concept disclosed herein relates to a light emitting diode, and more particularly, to a light emitting diode having a nanostructure capping pattern and a method of manufacturing the same.

### BACKGROUND ART

A light emitting diode (LED), a type of P-N junction diode, is a semiconductor device using electroluminescence, a phenomenon in which monochromatic light emits when a forward voltage is applied, and a wavelength of light emitted from the light emitting diode is determined by bandgap energy (Eg) of a material used therein. In an initial stage of light emitting diode technique, light emitting diodes capable of emitting infrared and red light had been mainly developed and blue LEDs have been actively studied after Nakamura of Nichia Chemical discovered that blue light can be generated by using GaN in 1993. Since white color may be made through a combination of red, green and blue colors, development of the blue light emitting diode based on GaN along with the already developed red and green light emitting diodes made possible to realize a white light emitting diode.

Meanwhile, in order to increase marketability of a light emitting diode, there is a need for increasing light-emitting efficiency and lifetime of the light emitting diode.

However, with respect to the blue light emitting diode based on GaN, only a portion of light generated in an active layer is used for emitting light and most of the generated light is reabsorbed in the diode to become extinct. As a result, external quantum efficiencies of most of blue light emitting diodes remain at a level of about 54%, but various techniques for increasing the light-emitting efficiency have recently been studied.

### DISCLOSURE OF INVENTION

### Technical Problem

The present inventive concept provides a nanostructure capping pattern covering a nanostructure to increase an external light-emitting efficiency and prevent damage of the nanostructure, which may occur during a manufacturing process.

The object of the present inventive concept is not limited to the aforesaid, but other objects not described herein will be clearly understood by those skilled in the art from descriptions below.

### Solution to Problem

Embodiments of the present inventive concept provide light emitting diodes including: a light-emitting structure including a first semiconductor layer, a second semiconductor layer, and an active layer between the first and second semiconductor layers; a nanostructure provided on the light-emitting structure; and a nanostructure capping pattern covering the nanostructure, wherein a refractive index of the nanostructure capping pattern may be higher than a refractive index of air and lower than a refractive index of the nanostructure.

In some embodiments, the nanostructure capping pattern may include a plurality of layers having different refractive indices and the refractive indices of the plurality of layers may gradually decrease from the layer in contact with the nanostructure to the layer in contact with air.

In other embodiments, the nanostructure capping pattern may include metal oxide. The metal oxide may include at least one of MgO, SiO, BeO, Lu₂O₃, Ta₂O₅, Y₂O₃, Yb₂O₃, and Al₂O₃.

In still other embodiments, the nanostructure capping pattern may include at least one of nickel (Ni), palladium (Pd), platinum (Pt), titanium (Ti), gold (Au), and copper (Cu).

In even other embodiments, a thickness of the nanostructure capping pattern may be in a range of about 100 Å to about 1000 Å

In yet other embodiments, the nanostructure capping pattern may cover a top surface and side surfaces of the nanostructure.

In further embodiments, the light emitting diode may further include a transparent electrode layer on the light-emitting structure, and the nanostructure may be provided on a surface of the transparent electrode layer.

In still further embodiments, the light emitting diode may further include a transparent electrode layer including a trench on the light-emitting structure, and the nanostructure may be provided in the trench.

In even further embodiments, the nanostructure may be provided on a surface of the first semiconductor layer.

In yet further embodiments, the nanostructure capping pattern may expose first and second electrodes.

In much further embodiments, the light emitting diode may further include metal islands in contact with the nanostructure.

In other embodiments of the present inventive concept, methods of manufacturing a light emitting diode include: forming a light-emitting structure including a first semi-conductor layer, a second semiconductor layer, and an active layer provided between the first and second semiconductor layers; forming a nanostructure on the light-emitting structure; forming a nanostructure capping pattern covering the nanostructure; and respectively forming a first electrode and a second electrode on the first semi-conductor layer and the second semiconductor layer, wherein a refractive index of the nanostructure capping pattern may be higher than a refractive index of air and lower than a refractive index of the nanostructure, and the nanostructure capping pattern may be formed earlier than the first and second electrodes.

In some embodiments, the forming of the nanostructure capping pattern may include depositing a plurality of layers having different refractive indices and the plurality of layers may be formed to allow the refractive indices to gradually decrease from the layer in contact with the nanostructure to the layer in contact with air.

In other embodiments, the forming of the nanostructure may include: forming a metal catalyst layer on the light-emitting structure; heat treating the metal catalyst layer to form metal islands; and using the metal islands as seeds to grow nanowires.

### Advantageous Effects of Invention

A light emitting diode including a nanostructure capping pattern is provided and thus, an external light-emitting efficiency may increase and damage of a nanostructure, which may occur during a manufacturing process, may be prevented.

### BRIEF DESCRIPTION OF DRAWINGS

The accompanying drawings are included to provide a further understanding of the present inventive concept, and are incorporated in and constitute a part of this specification. The drawings illustrate exemplary embodiments of the present inventive concept and, together with the description, serve to explain principles of the present inventive concept. In the drawings:

FIGS. 1 and 2 are plan view and cross-sectional view illustrating a light emitting diode according to an embodiment of the present inventive concept, respectively;

FIG. 3 is an enlarged view illustrating a nanostructure and a nanostructure capping pattern of FIGS. 1 and 2;

FIGS. 4 and 5 are plan view and cross-sectional view illustrating a light emitting diode according to another embodiment of the present inventive concept, respectively;

FIGS. 6 and 7 are cross-sectional views illustrating light emitting diodes according to other embodiments of the present inventive concept;

FIG. 8 is a flowchart for explaining a method of manufacturing a light emitting diode according to an embodiment of the present inventive concept; and

FIGS. 9 and 10 are cross-sectional views for explaining the method of manufacturing a light emitting diode according to the embodiment of the present inventive concept.

### BEST MODE FOR CARRYING OUT THE INVENTION

Advantages and features of the present inventive concept, and implementation methods thereof will be clarified through following embodiments described with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. Further, the present inventive concept is only defined by scopes of claims. Like reference numerals refer to like elements throughout.

In the specification, it will be understood that when a layer, such as a conductive layer, a semiconductor layer, or an insulating layer, is referred to as being “on” another layer or substrate, it can be directly on the other layer or substrate, or intervening layers may also be present. Also, though terms like a first, a second, and a third are used to describe various regions and layers in various embodiments of the present inventive concept, these terms are used only to discriminate one region or layer from another region or layer, and the regions and the layers are not limited to these terms.

In the following description, the technical terms are used only for explaining a specific exemplary embodiment while not limiting the present inventive concept. The terms of a singular form may include plural forms unless referred to the contrary. The meaning of “omprises” and/or “omprising” specifies a property, a region, a fixed number, a step, a process, an element and/or a component but does not exclude other properties, regions, fixed numbers, steps, processes, elements and/or components.

Additionally, the embodiment in the detailed description will be described with sectional views as ideal exemplary views of the present inventive concept. In the figures, the dimensions of layers and regions are exaggerated for clarity of illustration. Accordingly, shapes of the exemplary views may be modified according to manufacturing techniques and/or allowable errors. Therefore, the embodiments of the present inventive concept are not limited to the specific shape illustrated in the exemplary views, but may include other shapes that may be created according to manufacturing processes. For example, an etch region illustrated with right angles may be rounded or be configured with a predetermined curvature. Therefore, areas exemplified in the drawings have general properties, and are used to illustrate specific shapes of certain regions. Thus, this should not be construed as limited to the scope of the present inventive concept.

Hereinafter, a light emitting diode according to an embodiment of the present inventive concept and a method of manufacturing the light emitting diode will be described in detail with reference to the accompanying drawings.

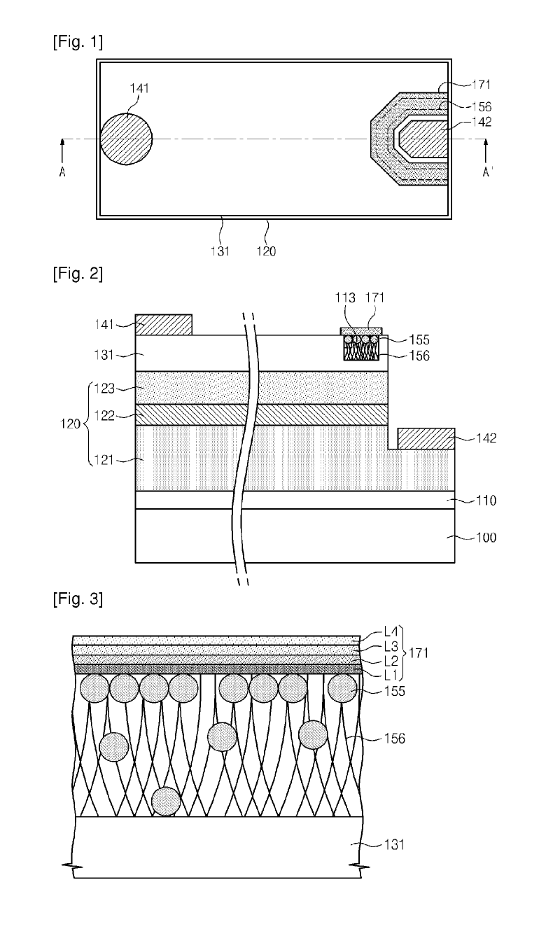

Referring to FIGS. 1 to 3, a light emitting diode according to an embodiment of the present inventive concept is provided. FIG. 1 is a plan view illustrating the light emitting diode according to the embodiment of the present inventive concept and FIG. 2 is a cross-sectional view taken along line A-A′ of FIG. 1. FIG. 3 is an enlarged view illustrating a nanostructure and a nanostructure capping pattern of FIGS. 1 and 2.

Referring to FIGS. 1 to 3, a light-emitting structure 120 may be provided on a substrate 100. The substrate 100 may be a sapphire, SiC, GaN, Si, or GaAs substrate, and single crystal oxide having a lattice constant close to a lattice constant of a nitride semiconductor may be used. The light-emitting structure 120 may include a first semi-conductor layer 121, an active layer 122, and a second semiconductor layer 123. A buffer layer 110 may be provided between the substrate 100 and the first semi-conductor layer 121. The buffer layer 110 may be an AlₓGa_{y}N_{1-x-y} layer (0<x<1, 0<y<1). Symbols such as x and y are used in order to express compositions in the present specification, but the symbols do not express a specific composition, and use of the same symbol does not refer to having the same composition. The buffer layer 110 may be a seed layer for forming an epitaxial layer from the substrate 100. The buffer layer 110 may decrease crystal defects generated due to differences in lattice constants and thermal expansion coefficients of the substrate 100 and the nitride semiconductor.

For example, the first semiconductor layer 121 may include an n-type contact layer and an n-type clad layer. The second semiconductor layer 123 may include a p-type contact layer and a p-type clad layer. The first semiconductor layer 121 may be an n-type GaₓN₁₋ₓ layer (0<x<1). The active layer 122 may include a multi quantum well (MQW) layer. The multi quantum well layer may emit light by recombination of electrons and holes. For example, the active layer 122 may be an InₓGa₁₋ₓN layer (0<x<1). The second semiconductor layer 123 may be a p-type GaₓN₁₋ₓ layer (0<x<1).

A transparent electrode layer 131 may be provided on the light-emitting structure 120. The transparent electrode layer 131 may transmit light radiating from the active layer 122 and may diffuse a current from a second electrode to be described below to an entire region of an upper surface of the light-emitting structure 120. The transparent electrode layer 131 may be a material including nickel (Ni) and gold (Au), or indium tin oxide (ITO). First electrode 142 and second electrode 141 are provided on the first semiconductor layer 121 and the transparent electrode layer 131, respectively. The first electrode 142 and the second electrode 141 are not limited to have shapes shown in FIG. 1, and may have various shapes, such as a circular, oval, rectangular, or triangular shape. The first electrode 142 and the second electrode 141 may include at least one of silver (Ag), aluminum (Al), gold (Au), palladium (Pd), nickel (Ni), zinc (Zn), molybdenum (Mo), tungsten (W), chromium (Cr), titanium (Ti), europium (Eu), platinum (Pt), and manganese (Mn).

A first nanostructure 156 may be provided on the transparent electrode layer 131. The first nanostructure 156 may be provided in a first trench 113 formed in the transparent electrode layer 131. For example, the first trench 113 may surround at least a portion of the first electrode 142. The first nanostructure 156 may be ZnₓO₁₋ₓ nanowires (0<x<1). The nanowires may be aligned in a direction substantially perpendicular to a bottom surface of the trench. The ZnₓO₁₋ₓ nanowires (0<x<1) have a diameter of about 100 nm or less and a height ranging from about 10 nm to about 1 μm, and thus, may be hair-shape nanostructures having a high aspect ratio. A refractive index of the first nanostructure 156 may be an intermediate value between a refractive index of the transparent electrode layer 131 and a refractive index of air. For example, when the refractive index of the transparent electrode layer 131 is 2.35 and the refractive index of air is 1.0, the refractive index of the first nanostructure 156 may be a value between 1.0 and 2.35. For example, when the first nanostructure 156 is ZnₓO₁₋ₓ nanowires (0<x<1), the refractive index of the first nanostructure 156 may be about 2.0. Therefore, the first nanostructure 156 may improve a light-emitting efficiency of the light-emitting diode by reducing reflection of the light generated from the active layer 122 at an interface between the transparent electrode layer 131 and air. For the simplicity of the description, only a single first trench 113 having the first nanostructure 156 provided therein is illustrated, but a plurality of the first trenches 113 may be formed in the transparent electrode layer 131, and the first nanostructure 156 may be formed in each of the plurality of first trenches 113. In this case, a nanostructure capping pattern to be described below may cover each of the plurality of first trenches 113.

Metal islands 155 in contact with the first nanostructure 156 may be provided. The metal islands 155 may be attached to an upper portion or intermediate portion of the first nanostructure 156, or may be provided on the bottom surface of the first trench 113. The metal islands 155 may be seeds for forming the ZnₓO₁₋ₓ nanowires (0<x<1) as described in a manufacturing method below. The metal islands 155 may include at least one of Au, cobalt (Co), lead (Pb), Pt, and Ni.

A nanostructure capping pattern 171 covering the first nanostructure 156 may be provided. A refractive index of the nanostructure capping pattern 171 may be higher than that of air and lower than that of the first nanostructure 156. For example, when the refractive index of air is 1.0 and the refractive index of the first nanostructure 156 is 2.0, the refractive index of the nanostructure capping pattern 171 may be greater than 1.0 and smaller than 2.0. When the refractive index of the nanostructure capping pattern 171 is higher than that of air and lower than that of the first nanostructure 156, an amount of light not reflecting at an end of the first nanostructure 156 but radiating to the outside may increase. Such a phenomenon may be explained according to Snell s law in Equation 1.

$$\frac{Sin {θ}_{1}}{Sin {θ}_{2}} = \frac{{n}_{2}}{{n}_{1}}$$

(θ₁ is an incident angle for transmitting the first nanostructure, θ₂ is a refraction angle for refracting from the nanostructure capping pattern, n₁ is a refractive index of the first nanostructure, and n₂ is a refractive index of the nanostructure capping pattern)

That is, a critical angle of θ₁ at which a total reflection (θ₂=90°) occurs may increase as the refractive index n₂ of the nanostructure capping pattern 171 is higher. Such a phenomenon may be similarly applied to an interface between the nanostructure capping pattern 171 and air, and thus, when the refractive index of the nanostructure capping pattern 171 is an intermediate value between the refractive index of air and the refractive index of the first nanostructure 156, the light-emitting efficiency of the light emitting diode may increase because possibility of the light generated from the active layer 122 being emitted to the outside increases.

The nanostructure capping pattern 171 may be a single layer. In another embodiment of the present inventive concept, the nanostructure capping pattern 171 may include a plurality of layers having different refractive indices and the refractive indices of the plurality of layers may gradually decrease from the layer in contact with the first nanostructure 156 to the layer in contact with air. For example, the nanostructure capping pattern 171 may include four layers, L1, L2, L3, and L4, as shown in FIG. 3, and refractive indices of the four layers may satisfy L1>L2>L3>L4.

A material for the nanostructure capping pattern 171 may include at least one of materials in Table 1. When the nanostructure capping pattern 171 includes a plurality of layers having different refractive indices as described above, the plurality of layers may be selected from Table 1 so as to allow the refractive indices to gradually decrease from the layer in contact with the first nanostructure 156 to the layer in contact with air.

TABLE 1

| Oxide base | | Metal base | |
|---|---|---|---|
| Material | Refractive index | Material | Refractive index |
| MgO | 1.75 | Ni | 1.628 |
| SiO | 1.55 | Pd | 1.4 |
| BeO | 1.7 | Pt | 1.84 |
| Lu₂O₃ | 1.92 | Ti | 1.69 |
| Ta₂O₅ | 1.79 | Au | 1.5 |
| Y₂O₃ | 1.92 | Cu | 1.16 |
| Yb₂O₃ | 1.94 | — | — |
| Al₂O₃ | 1.67 | — | — |

A thickness of the nanostructure capping pattern 171 may be in a range of about 100 Å to about 1000 Å. The nanostructure capping pattern 171 may be restrictively provided on the first nanostructure 56 and may expose the first and second electrodes 141 and 142. Alternatively, a portion of the nanostructure capping pattern 171 may exist between the nanowires constituting the first nanostructure 156.

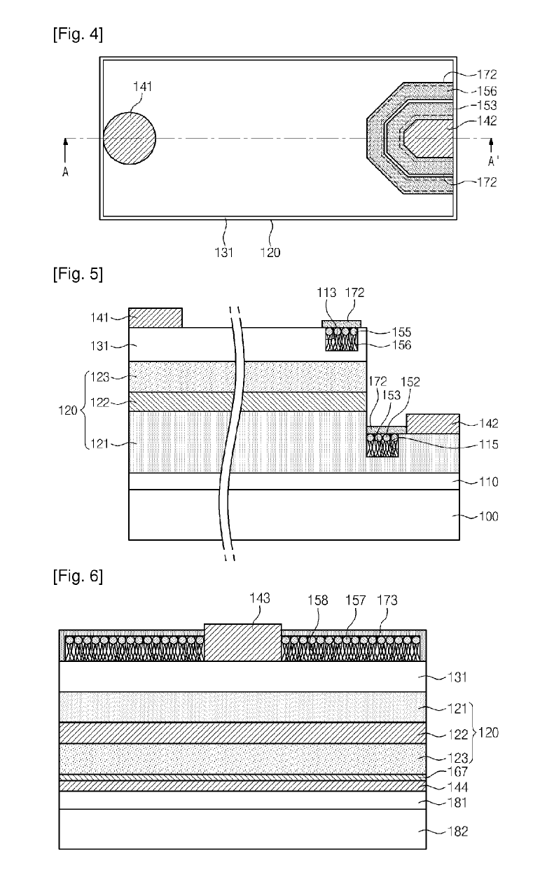

FIGS. 4 and 5 are plan view and cross-sectional view illustrating a light emitting diode according to another embodiment of the present inventive concept, respectively. FIG. 5 is a cross-sectional view taken along line A-A′ of FIG. 4. For the simplicity of the description, the description related to the overlapping configuration will not be provided.

In the embodiment of the present inventive concept, a second nanostructure 153 may be provided in a second trench 115 formed in the first semiconductor layer 121. The second trench 115 may surround at least a portion of the first electrode 142. The second nanostructure 153 may be ZnₓO₁₋ₓ nanowires (0<x<1). Metal islands 152 in contact with the second nanostructure 153 may be provided. The second nanostructure 153 and the metal islands 152 may be substantially the same structure and material as the foregoing first nanostructure 156 and metal islands 155.

Nanostructure capping patterns 172 respectively covering the first and second nanostructures 153 and 156 may be provided. A shape of the nanostructure capping pattern 172 is not limited thereto and any shape covering the first and second nanostructures 153 and 156 may be possible. For example, the nanostructure capping pattern 172 may be provided on the first and second nanostructures 153 and 156 in each separate form. The nanostructure capping pattern 172 may include a plurality of layers as shown in FIG. 3. For the simplicity of the description, only one first trench 113 having the first nanostructure 156 provided therein is illustrated, but a plurality of the first trenches 113 may be formed in the transparent electrode layer 131 and the first nanostructure 156 may be formed in each of the plurality of first trenches 113. In this case, the nanostructure capping pattern 172 may cover each of the plurality of first trenches 113.

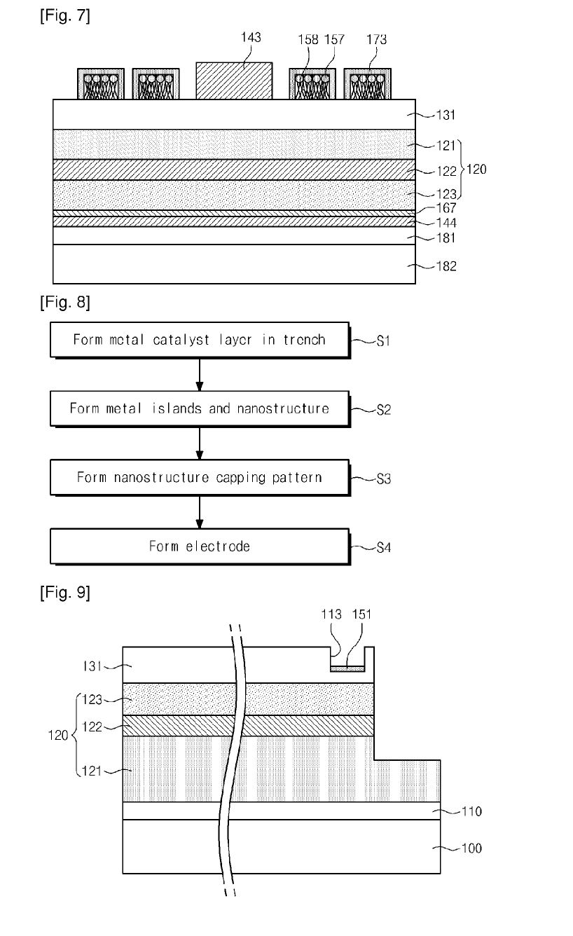

FIGS. 6 and 7 are cross-sectional views illustrating light emitting diodes according to other embodiments of the present inventive concept. For the simplicity of the description, the description related to the overlapping configuration will not be provided.

A second electrode 144 may be provided on a structure support layer 182. The structure support layer 182 may support a light-emitting structure after separation of a substrate (not shown). The structure support layer 182 may be formed of a silicon substrate or a metal substrate. The structure support layer 182 may be attached to the second electrode 144 by an adhesive layer 181. The adhesive layer 181 may include at least one of gold (Au), indium (In), palladium (Pd), and tin (Sn).

A light-emitting structure 120 may be provided on the second electrode 144. The light-emitting structure 120 may include a first semiconductor layer 121, a second semiconductor layer 123, and an active layer 122 between the first and second semi-conductor layers 121 and 123. A reflective layer 167 may be provided between the light-emitting structure 120 and the second electrode 144. The reflective layer 167 may be formed of metal including at least one of Al, Ag, copper (Cu), AgCu, Ni, rhodium (Rh), Pd, Pt, ruthenium (Ru), and Au, or may include conductive metal oxides such as MgZnO doped with TiO, NiO, indium, or gallium, InO doped with gallium, or ZnO doped with gallium. The reflective layer 167 may reflect light, which is generated from the active layer 122 and emitted in a direction of the second semiconductor layer 123, to a direction of the first semiconductor layer 121. In another embodiment of the present inventive concept, the reflective layer 167 is not provided and a portion of the second electrode 144 may act as a reflective layer.

A transparent electrode layer 131 and a first electrode 143 may be sequentially provided on the light-emitting structure 120. A nanostructure 158 may be provided on a surface of the transparent electrode layer 131. The nanostructure 158 may cover an entire surface of the exposed transparent electrode layer 131 as shown in FIG. 6 or may be provided in a cluster form separated from one another on the transparent electrode layer 131 as shown in FIG. 7. Metal islands 157 in contact with the nanostructure 158 may be provided.

A nanostructure capping pattern 173 covering the nanostructure 158 may be provided. The nanostructure capping pattern 173 may cover a top surface and side surfaces of the nanostructure 158. For example, when the nanostructure 158 includes mutually separated clusters as shown in FIG. 7, the nanostructure capping pattern 173 may cover a top surface and side surfaces of the each cluster constituting the nanostructure 158. The nanostructure capping pattern 173 may include a plurality of layers as show in FIG. 3. Structures of FIGS. 6 and 7 may be applied to the embodiments of FIGS. 2 and 5. That is, the first nanostructure 156 in the embodiments of FIGS. 2 and 5 may be formed on the surface of the transparent electrode layer 131 without a trench as in the nanostructure 158 of FIGS. 6 and 7.

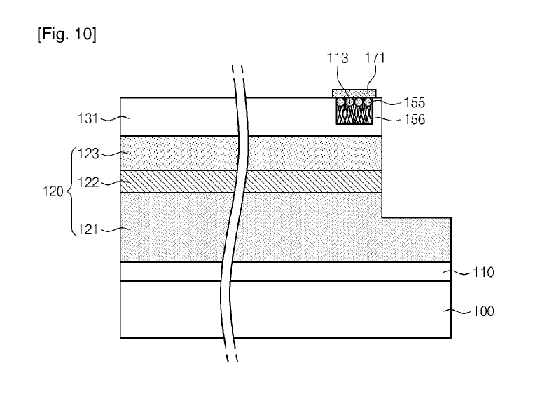

FIG. 8 is a flowchart for explaining a method of manufacturing a light emitting diode according to an embodiment of the present inventive concept. FIGS. 9 and 10 are cross-sectional views for explaining the method of manufacturing a light emitting diode according to the embodiment of the present inventive concept. For the simplicity of the description, the following manufacturing method is described based on the light emitting diode according to the embodiment of FIGS. 1 to 3, but may be identically or similarly applied to the embodiments of FIGS. 4 to 7.

Referring to FIGS. 8 and 9, A metal catalyst layer 151 may be formed on a first trench 113 formed in the transparent electrode layer 131 (S1). The metal catalyst layer 151 may be formed of a material including at least one of Au, Co, Pb, Pt, and Ni. The metal catalyst layer 151 may be formed by electron-beam evaporation, sputtering, or metalorganic chemical vapor deposition (MOCVD) after masking a portion other than the first trench 113 with a mask. The forming of the first trench 113 and the forming of the metal catalyst layer 151 may be performed by using the same mask.

Referring to FIGS. 8 and 10, Metal islands 155 may be formed by heat treating the metal catalyst layer 151 (S2). The heat treatment process may be performed within a temperature range of about 300° C. to about 900° C. The metal catalyst layer 151 may become nano-sized metal islands 155 by the heat treatment. A size of the metal islands 155 may be in a range of a few Å to a few hundreds nanometer. A first nanostructure 156 may be formed by using the metal islands 155 as seeds (S2). The first nanostructure 156 may be ZnₓO₁₋ₓ nanowires (0<x<1). The nanowires may be grown between a bottom surface of the first trench 113 and the metal islands 155 or may be grown from an upper portion of the metal islands 155. Therefore, after completion of the growth, the metal islands 155 may exist under the first nanostructure 156 or may exist at an upper portion or an intermediate portion of the first nanostructure 156. For the sake of convenience, FIG. 10 illustrates that the metal islands 155 exist on the first nanostructure 156. The nanowires may be grown from the metal islands 155 by charging zinc oxide (ZnO) powder or zinc (Zn) powder into a reaction furnace of a thermal chemical vapor deposition (CVD) equipment and supplying Ar gas and N₂ gas. Also, the nanowires may be formed by molecular beam epitaxy (MBE). Further, the nanowires may be formed by metalorganic CVD (MOCVD) by using a precursor, such as dimethyl-zinc (DMZn), and O₂ gas. The forming of the metal islands 155 and the forming of the first nanostructure 156 may be performed in the same reaction furnace.

A nanostructure capping pattern 171 may be formed on the first nanostructure 156 (S3). A refractive index of the nanostructure capping pattern 171 may be higher than that of air and may be lower than that of the first nanostructure 156. For example, when the refractive index of air is 1.0 and the refractive index of the first nanostructure 156 is 2.0, the refractive index of the nanostructure capping pattern 171 may be greater than 1.0 and smaller than 2.0. The nanostructure capping pattern 171 may include a plurality of layers having different refractive indices as shown in FIG. 3 and the refractive indices of the plurality of layers may gradually decrease from the layer in contact with the first nanostructure 156 to the layer in contact with air.

The nanostructure capping pattern 171 may be formed by various methods according to the type of materials described in Table 1. For example, the nanostructure capping pattern 171 may be formed by sputtering, e-beam evaporation, MOCVD, or atomic layer deposition (ALD). The formation of the nanostructure capping pattern 171 may include an etching process using a photoresist. The transparent electrode layer 131 and the first semiconductor layer 121 may be exposed by the etching process.

Referring to FIGS. 1 and 2 again, a first electrode 142 and a second electrode 141 may be formed on the first semiconductor layer 121 and the transparent electrode layer 131, respectively (S4). That is, the nanostructure capping pattern 171 may be formed earlier than the electrodes 141 and 142. The nanostructure capping pattern 171 may prevent damage or separation of the first nanostructure 156 during a process after the forming of the first nanostructure 156, such as the forming of the electrodes 141 and 142.

The above detailed description exemplifies and explains the present inventive concept. Also, the foregoing description is merely provided to present and describe preferred embodiments of the present inventive concept. The above-disclosed subject matter is to be considered illustrative, and not restrictive, and the appended claims are intended to cover all such modifications, enhancements, and other embodiments, which fall within the true spirit and scope of the present inventive concept. Thus, to the maximum extent allowed by law, the scope of the present inventive concept is to be determined by the broadest permissible interpretation of the following claims and their equivalents, and shall not be restricted or limited by the foregoing detailed description.

### INDUSTRIAL APPLICABILITY

The present inventive concept may be used in semiconductor device, especially in LED industry.

1. A light emitting diode comprising:
a light-emitting structure including a first semiconductor layer, a second semiconductor layer, and an active layer between the first and second semiconductor layers;
a nanostructure provided on the light-emitting structure; and
a nanostructure capping pattern covering the nanostructure,
wherein a refractive index of the nanostructure capping pattern is higher than a refractive index of air and is lower than a refractive index of the nanostructure.

2. The light emitting diode of claim 1, wherein the nanostructure capping pattern comprises a plurality of layers having different refractive indices and the refractive indices of the plurality of layers gradually decrease from the layer in contact with the nanostructure to the layer in contact with air.

3. The light emitting diode of claim 1, wherein the nanostructure capping pattern comprises metal oxide.

4. The light emitting diode of claim 3, wherein the metal oxide comprises at least one of MgO, SiO, BeO, Lu₂O₃, Ta₂O₅, Y₂O₃, Yb₂O₃, and Al₂O₃.

5. The light emitting diode of claim 1, wherein the nanostructure capping pattern comprises at least one of Ni (nickel), Pd (palladium), Pt (platinum), Ti (titanium), Au (gold), and Cu (copper).

6. The light emitting diode of claim 1, wherein a thickness of the nanostructure capping pattern is in a range of about 100 Å to about 1000 Å.

7. The light emitting diode of claim 1, wherein the nanostructure capping pattern covers a top surface and side surfaces of the nanostructure.

8. The light emitting diode of claim 1, further comprising a transparent electrode layer on the light-emitting structure,
wherein the nanostructure is provided on a surface of the transparent electrode layer.

9. The light emitting diode of claim 1, further comprising a transparent electrode layer including a trench on the light-emitting structure,
wherein the nanostructure is provided in the trench.

10. The light emitting diode of claim 1, wherein the nanostructure is provided on a surface of the first semiconductor layer.

11. The light emitting diode of claim 1, further comprising a first electrode on the first semiconductor layer and a second electrode on the second semiconductor layer,
wherein the nanostructure capping pattern exposes the first and second electrodes.

12. The light emitting diode of claim 1, further comprising metal islands in contact with the nanostructure.

13. A method of manufacturing a light emitting diode, the method comprising:
forming a light-emitting structure including a first semiconductor layer, a second semiconductor layer, and an active layer provided between the first and second semiconductor layers;
forming a nanostructure on the light-emitting structure;
forming a nanostructure capping pattern covering the nanostructure; and
forming a first electrode on the first semiconductor layer and a second electrode on the second semiconductor layer,
wherein a refractive index of the nanostructure capping pattern is higher than a refractive index of air and is lower than a refractive index of the nanostructure, and the nanostructure capping pattern is formed earlier than the first and second electrodes.

14. The method of claim 13, wherein the forming of the nanostructure capping pattern comprises depositing a plurality of layers having different refractive indices and the plurality of layers are formed to allow the refractive indices to gradually decrease from the layer in contact with the nanostructure to the layer in contact with air.

15. The method of claim 13, wherein the forming of the nanostructure comprises:
forming a metal catalyst layer on the light-emitting structure;
heat treating the metal catalyst layer to form metal islands; and
using the metal islands as seeds to grow nanowires.
